(19) United States
(12) Patent Application Publication
(10) Pub. No.: US 2006/0008962 A1
(43) Pub. Date: Jan. 12, 2006

(54) Manufacturing method of semiconductor integrated circuit device

(75) Inventors: Kazuyuki Ozeki, Gunma (JP); Yuji Tsukada, Gunma (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Moriguchi-shi (JP)

(21) Appl. No.: 11/175,049

(22) Filed: Jul. 6, 2005

(30) Foreign Application Priority Data
Jul. 6, 2004 (JP) 2004-198960

(51) Int. Cl. H01L 21/336; H01L 21/8234

(52) U.S. Cl. 438/197

(57) ABSTRACT

The invention is directed to a semiconductor integrated circuit device having a plurality of gate insulation films of different thicknesses where reliability of the gate insulation films and characteristics of MOS transistors are improved. A photoresist layer is selectively formed on a SiO₂ film in first and third regions, and a SiO₂ film in a second region is removed by etching. After the photoresist layer is removed, a silicon substrate is thermally oxidized to form a SiO₂ film having a smaller thickness than a first gate insulation film in the second region. Then, the SiO₂ film in the third region is removed by etching. After a photoresist layer is removed, the silicon substrate is thermally oxidized to form a SiO₂ film having a smaller thickness than a second gate insulation film in the third region.

### CROSS-REFERENCE OF THE INVENTION

This invention is based on Japanese Patent Application No. 2004-198960, the content of which is incorporated by reference in its entirety.

### BACKGROUND OF THE INVENTION

1. Field of the Invention

The invention relates to a manufacturing method of a semiconductor integrated circuit device, particularly to a manufacturing method of a semiconductor integrated circuit device having a plurality of gate insulation films of different thicknesses.

2. Description of the Related Art

Large scale integration and high performance of a semiconductor integrated circuit device have been pursued in recent years. For example, a system LSI having a memory such as a flash memory or a high voltage MOS transistor has been developed.

When a low voltage MOS transistor and a high voltage MOS transistor are integrally formed on a same semiconductor substrate in such a semiconductor integrated circuit device, a gate insulation film is formed thin in the low voltage MOS transistor for miniaturization and a gate insulation film is formed thick in the high voltage MOS transistor for securing a high gate insulation breakdown voltage. For forming a plurality of gate insulation films of different thicknesses on the same semiconductor substrate, there has been generally known such a method that a thick gate insulation film is formed, the thick gate insulation film is selectively etched, and a thin gate insulation film is formed by thermal oxidation. The relevant technology is disclosed in the Japanese Patent Application Publication No. 2003-60074.

However, repeating such etching and thermal oxidation causes problems such as degradation of reliability of the gate insulation films or a bad effect on transistor characteristics because of a field oxidation film made thin by etching.

### SUMMARY OF THE INVENTION

The invention provides a method of manufacturing a semiconductor integrated circuit device. The method includes providing a semiconductor substrate, forming a first field insulation film in a first region of the substrate, a second field insulation film in a second region of the substrate and a third field insulation film in a third region of the substrate, exposing the first, second and third regions that are not covered by the first, second and third field insulation films, and forming in one process step a first insulator film in the exposed first region, a second insulator film in the exposed second region and a third insulator film on the exposed third region. The first, second and third insulator films have substantially a same thickness. The method also include etching the second insulator film to expose the second region while protecting the first and third regions form etching, oxidizing the exposed second region to form a first gate insulation film, etching the third insulator film to expose the third region while protecting the first and second regions form etching, oxidizing the exposed third region to form a second gate insulation film, and forming a gate electrode on each of the first insulator film, the first gate insulation film and the second gate insulation film.

### BRIEF DESCRIPTION OF THE DRAWINGS

FIGS. 1A, 1B, 1C, and 1D are cross-sectional views of device intermediates at process steps of a manufacturing method of a semiconductor integrated circuit device of a comparative example of the invention.

FIGS. 2A, 2B, 2C, and 2D are cross-sectional views of device intermediates of process steps following the steps of FIGS. 1A-1D.

FIGS. 3A and 3B are cross-sectional views of device intermediates of process steps following the steps of FIGS. 2A-2D.

FIGS. 4A and 4B are views showing a structure of a MOS transistor of the semiconductor integrated circuit device of the comparative example of the invention.

FIGS. 5A and 5B show characteristics of the MOS transistor of the semiconductor integrated circuit device of the comparative example of the invention.

FIGS. 6A, 6B, 6C, and 6D are cross-sectional views of device intermediates at process steps of a manufacturing method of a semiconductor integrated circuit device of an embodiment of the invention.

FIGS. 7A, 7B, and 7C are cross-sectional views of device intermediates of process steps following the steps of FIGS. 6A-6D.

### DETAILED DESCRIPTION OF THE INVENTION

A manufacturing method of a semiconductor integrated circuit device of an embodiment of the invention will be described with reference to drawings. First, a comparative example to be compared with the manufacturing method of the semiconductor integrated circuit device of the embodiment of the invention will be described.

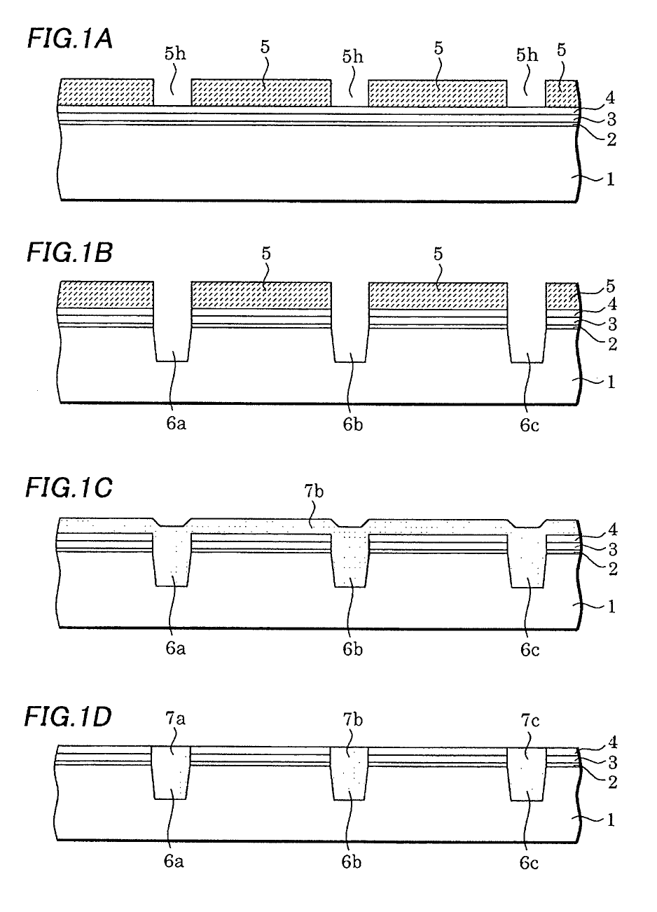

As shown in FIG. 1A, a SiO₂ film 2 (silicon dioxide film) of about 10 nm is formed on a front surface of a P-type silicon substrate 1 by thermal oxidation. Then, a polysilicon film 3 having a thickness of about 50 nm and a Si₃N₄ film (silicon nitride film) 4 having a thickness of 120 nm are formed on the SiO₂ film 2 by a CVD method. Furthermore, a photoresist layer 5 having a plurality of openings 5h is formed on the Si₃N₄ film 4.

Next, as shown in FIG. 1B, by using the photoresist layer 5 having the plurality of openings 5h as a mask, the Si₃N₄ film 4, the polysilicon film 3, and the SiO₂ film 2 exposed in the openings 5h are etched in this order, and the front surface of the P-type silicon substrate 1 is further etched, thereby forming trenches 6a, 6b, and 6c. It is preferable that the trenches 6a, 6b, and 6c are 1 μm or less in depth for so-called shallow trench isolation.

Next, as shown in FIG. 1C, a SiO₂ film (e.g. a TEOS film) 7 is formed on the whole surface including in the trenches 6a, 6b, and 6c by the CVD method. Then, the front surface of the SiO₂ film 7 is polished by a CMP method (a chemical mechanical polishing method) as shown in FIG. 1D. In this process, the Si₃N₄ film 4 functions as an endpoint detection film for the CMP, and the CMP is stopped when the exposed Si₃N₄ film 4 is detected by an optical method. In this manner, trench insulation films 7a, 7b, and 7c selectively embedded in the trenches 6a, 6b, and 6c are formed as field insulation films.

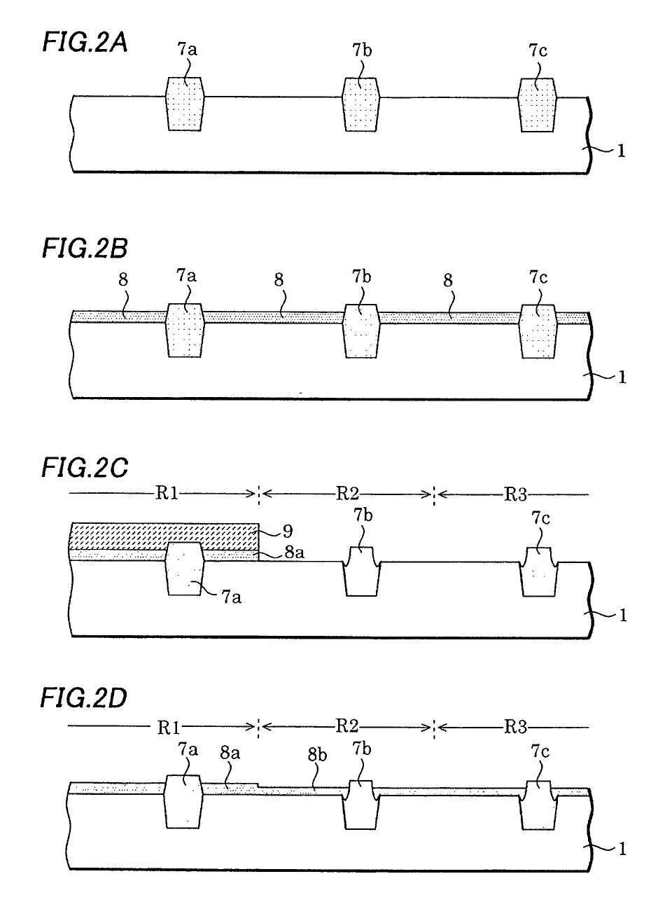

Then, as shown in FIG. 2A, the Si₃N₄ film 4 is removed using chemical such as hot phosphoric acid, the polysilicon film 3 is removed by dry-etching, and the SiO₂ film 2 is removed by etching according to needs. The shallow trench isolation structure suitable for miniaturization is thus formed as a device isolation structure.

Next, as shown in FIG. 2B, a SiO₂ film (e.g. a thermal oxidation film, or a TEOS film by a CVD method) 8 is formed on the front surface of the silicon substrate 1 formed with the trench insulation films 7a, 7b, and 7c, adjacent to the trench insulation films 7a, 7b, and 7c, so as to have a thickness of 20 nm for example.

Next, as shown in FIG. 2C, a photoresist layer 9 is selectively formed on the SiO₂ film 8 in a first region R1 by exposure and development. By using this photoresist layer 9 as a mask, the SiO₂ film 8 in second and third regions R2 and R3 adjacent to the photoresist layer 9 is removed by etching to expose the front surface of the silicon substrate 1. A SiO₂ film 8a remaining in the first region R1 is to serve as a first gate insulation film 8a (thickness T1=20 nm). In this etching process, the trench insulation film 7b in the second region R2 and the trench insulation film 7c in the third region R3 are etched, so that the height from the front surface of the silicon substrate 1 to tops of the films 7b and 7c is reduced and edges of the films 7b and 7c are gouged.

Next, as shown in FIG. 2D, after the photoresist layer 9 is removed, the silicon substrate 1 is thermally oxidized to form a SiO₂ film 8b having a smaller thickness than the first gate insulation film 8a, for example, 7 nm, in the second and third regions R2 and R3. The SiO₂ film 8b formed in the second region R2 is to serve as a second gate insulation film 8b (thickness T2=7 nm).

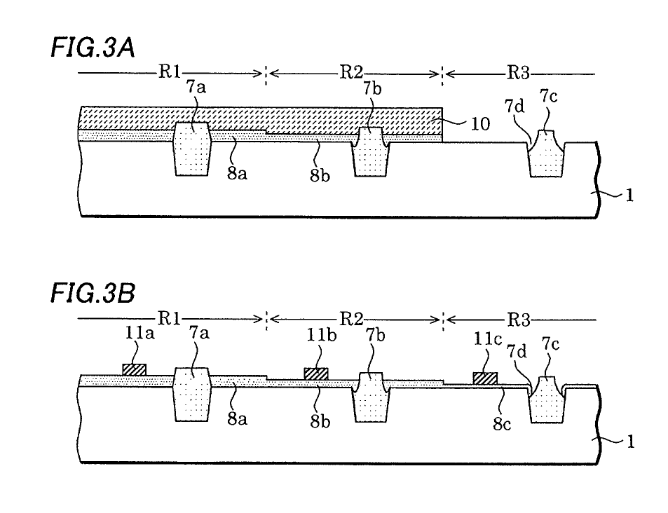

Next, as shown in FIG. 3A, the first region R1 and the second region R2 are covered with a photoresist layer 10 and the SiO₂ film 8b in the third region R3 is removed by etching, so that the silicon substrate 1 is exposed there.

Next, as shown in FIG. 3B, after the photoresist layer 10 is removed, the silicon substrate 1 is thermally oxidized to form a SiO₂ film 8c having a smaller thickness than the second gate insulation film 8b, for example, 3 nm, in the third region R3. The SiO₂ film 8c is to serve as a third gate insulation film 8c (thickness T3=3 nm). Then, a gate electrode 11a, a gate electrode 11b, and a gate electrode 11c are formed on the first gate insulation film 8a, the second gate insulation film 8b, and the third gate insulation film 8c, respectively. Furthermore, a source layer and a drain layer are formed adjacent to each of the gate electrodes 11a, 11b, and 11c. Accordingly, a high voltage MOS transistor is formed in the first region R1, a medium voltage MOS transistor is formed in the second region R2, and a low voltage MOS transistor is formed in the third region R3.

However, in this comparative example of the manufacturing method of the semiconductor integrated circuit device, since the third region R3 undergoes the etching process twice, the reliability of, especially, the third gate insulation film 8c is affected. Furthermore, the trench insulation film 7c in the third region R3 is consumed in the two etching processes, so that the height from the front surface of the silicon substrate 1 to the top of the trench insulation film 7c is largely reduced compared with the trench insulation film 7a in the first region R1 and the trench insulation film 7b in the second region R2, thereby degrading device isolation characteristics. Although the trench insulation films 7a, 7b, and 7c may be formed thick in advance for solving the problems, this causes a problem that the trench insulation film 7a in the first region R1 which undergoes no etching process is formed too thick, so that a stringer of a gate electrode material (e.g. polysilicon) occurs in a sidewall of the trench insulation film 7a when the gate electrode is formed.

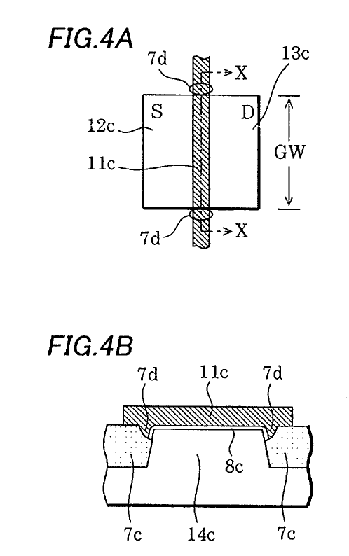

Furthermore, the trench insulation film 7c in the third region R3 is largely gouged in the second etching process to form a concave portion 7d. FIGS. 4A and 4B are views showing the low voltage MOS transistor formed in the third region R3. FIG. 4A is a plan view thereof and FIG. 4B is a cross-sectional view along line X-X of FIG. 4A.

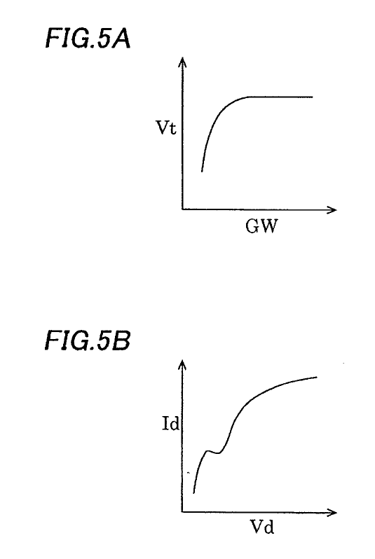

In FIGS. 4A and 4B, a numeral 12c designates a source layer, a numeral 13c designates a drain layer, and a numeral 14c designates a channel region. As shown in FIGS. 4A and 4B, this MOS transistor has such a structure that a part of the gate electrode 11c enters the concave portions 7d of the trench insulation film 7c. In this MOS transistor, an inverse narrow channel effect, where a threshold value Vt reduces when a channel length GW reduces, occurs as shown in FIG. 5A. Furthermore, a kink occurs in drain current (Id) characteristics as shown in FIG. 5B.

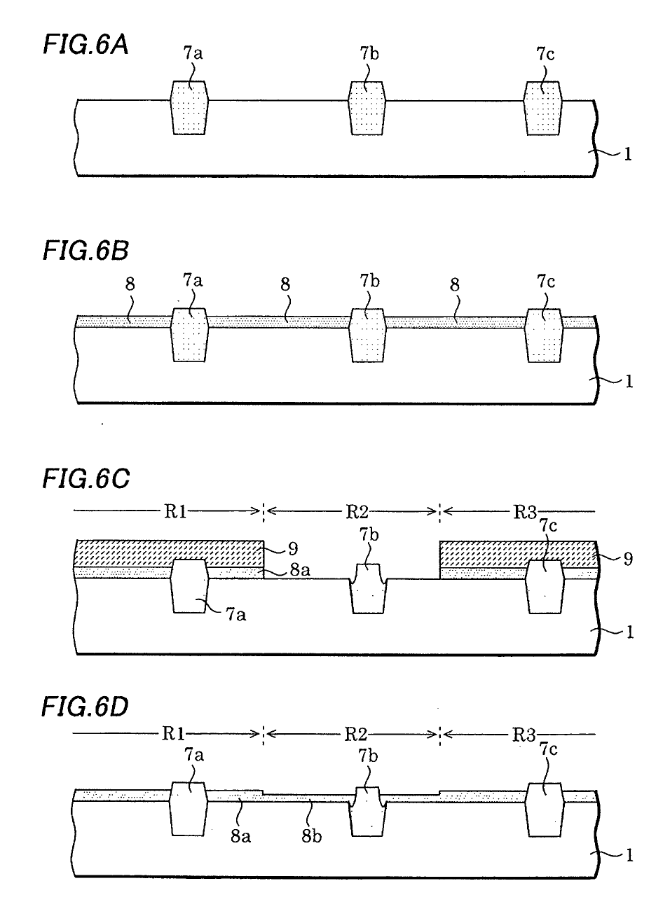

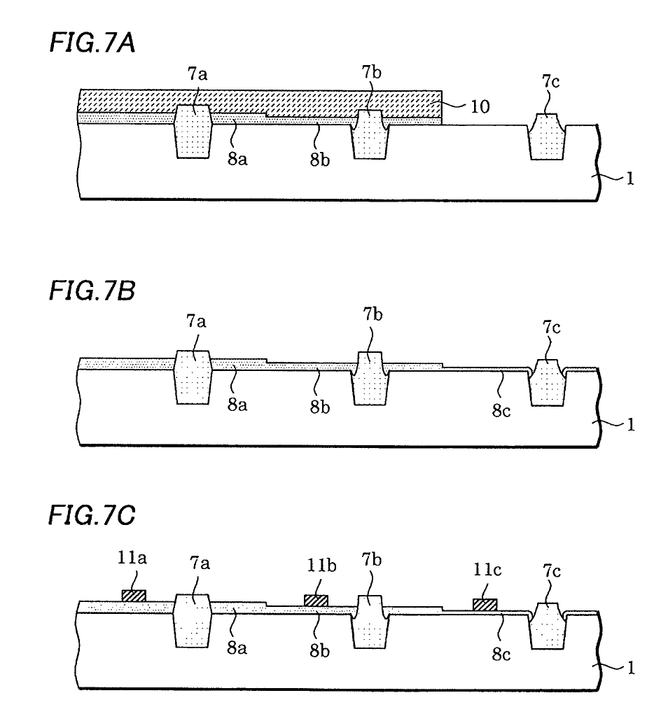

Hereafter, a manufacturing method of a semiconductor integrated circuit device of an embodiment of the invention will be described with reference to FIGS. 6A-7C. In this embodiment, the number of etching processes for forming the plurality of gate insulation films is reduced for solving the problems of the comparative example.

As shown in FIG. 6A, the trench insulation films 7a, 7b, and 7c are formed on the front surface of the P-type silicon substrate 1 by the same method as that of the comparative example. Then, as shown in FIG. 6B, the SiO₂ film 8 (e.g., a thermal oxidation film, or a TEOS film by a CVD method) is formed adjacent to the trench insulation films 7a, 7b, and 7c, so as to have a thickness of, for example, 20 nm.

Next, as shown in FIG. 6C, the photoresist layer 9 is selectively formed on the SiO₂ film 8 in the first and third regions R1 and R3 by exposure and development. Then, by using this photoresist layer 9 as a mask, the SiO₂ film 8 in the second region R2 adjacent to the photoresist layer 9 is removed by etching to expose the front surface of the silicon substrate 1. The SiO₂ film 8a remaining in the first region R1 is to serve as the first gate insulation film 8a (thickness T1=20 nm). In this etching process, the trench insulation film 7b in the second region R2 is etched, so that the height from the front surface of the silicon substrate 1 to the top of the trench insulation film 7b is reduced and the edges of the trench insulation film 7b is gouged. On the other hand, the trench insulation film 7a in the first region R1 and the trench insulation film 7c in the third region R3 are not etched since these are covered with the photoresist layer 9.

Next, as shown in FIG. 6D, after the photoresist layer 9 is removed, the silicon substrate 1 is thermally oxidized to form the SiO₂ film 8b having a smaller thickness than the first gate insulation film 8a, for example, 7 nm, in the second region R2. The SiO₂ film 8b formed in the second region R2 is to serve as the second gate insulation film 8b (thickness T2=7 nm). It is noted that the first gate insulation film 8a formed on the first and third regions R1 and R3 grows a little during the formation of the SiO₂ film 8b.

Next, as shown in FIG. 7A, the first and second regions R1 and R2 are covered with the photoresist layer 10 and the SiO₂ film 8b in the third region R3 is removed by etching, so that the silicon substrate 1 is exposed. In this etching process, the trench insulation film 7c in the third region R3 is etched, so that the height from the front surface of the silicon substrate 1 to the top of the trench insulation film 7c is reduced and the edges of the trench insulation film 7c is gouged. However, different from the comparative example, the trench insulation film 7c is etched only once, and thus the gouged amount thereof is small relatively. It is noted that the height of the trench insulation film 7c is smaller than that of the trench insulation film 7b and the depth of the pocket formed around the trench insulation film 7c are larger than that of the trench insulation film 7b because the gate insulation film 8a on the third region R3 have grown during the formation of the SiO₂ film 8b as explained above.

Next, as shown in FIG. 7B, after the photoresist layer 10 is removed, the silicon substrate 1 is thermally oxidized to form the SiO₂ film 8c having a smaller thickness than the second gate insulation film 8b, for example, 3 nm, in the third region R3. This SiO₂ film 8c is to serve as the third gate insulation film 8c (thickness T3=3 nm). Then, in the same manner as that of the comparative example, the gate electrode 11a, the gate electrode 11b, and the gate electrode 11c are formed on the first gate insulation film 8a, the second gate insulation film 8b, and the third gate insulation film 8c, respectively. The source layer and the drain layer are then formed adjacent to each of the gate electrodes 11a, 11b, and 11c. Accordingly, the high voltage MOS transistor is formed in the first region R1, the medium voltage MOS transistor is formed in the second region R2, and the low voltage MOS transistor is formed in the third region R3.

In this embodiment, the first region R1 is not etched, and the second and third regions R2 and R3 are etched only once, so that the problem of degrading the reliability of the third gate insulation film 8c as has been seen in the comparative example can be solved. Furthermore, the etching amount of the trench insulation film 7c is reduced, so that the device isolation characteristics is improved. Furthermore, the degradation of the characteristics of the MOS transistor caused by over-cutting the trench insulation film 7c can be prevented. For example, the inverse narrow channel effect or the kink in the drain current characteristics as has been seen in the MOS transistor of the comparative example can be prevented.

What is claimed is:

1. A method of manufacturing a semiconductor integrated circuit device, comprising:
providing a semiconductor substrate;
forming a first field insulation film in a first region of the substrate, a second field insulation film in a second region of the substrate and a third field insulation film in a third region of the substrate;
exposing the first, second and third regions that are not covered by the first, second and third field insulation films;
forming in one process step a first insulator film in the exposed first region, a second insulator film in the exposed second region and a third insulator film on the exposed third region, the first, second and third insulator films having substantially a same thickness;
etching the second insulator film to expose the second region while protecting the first and third regions form etching;
oxidizing the exposed second region to form a first gate insulation film;
etching the third insulator film to expose the third region while protecting the first and second regions form etching;
oxidizing the exposed third region to form a second gate insulation film; and
forming a gate electrode on each of the first insulator film, the first gate insulation film and the second gate insulation film.

2. The method of claim 1, wherein a thickness of the first gate insulation film is larger than a thickness of the second gate insulation film and smaller than a thickness of the first insulator film.

3. The method of claim 1, wherein each of the filed insulation film comprises a trench insulation film.

4. The method of claim 1, wherein the forming of the first, second and third insulator films comprising oxidizing the substrate.

5. The method of claim 1, wherein the forming of the first, second and third insulator films comprising depositing silicon dioxide.
